(19) United States
(12) Patent Application Publication
(10) Pub. No.: US 2025/0227975 A1
(43) Pub. Date: Jul. 10, 2025

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Hung-Ju CHOU, Hsinchu (TW); Wei-Yang LEE, Taipei City (TW); Yuan-Ching PENG, Hsinchu (TW)

(73) Assignee: Taiwan Semiconductor Manufacturing Company, Ltd., Hsinchu (TW)

(21) Appl. No.: 18/618,482

(22) Filed: Mar. 27, 2024

Related U.S. Application Data
(60) Provisional application No. 63/617,504, filed on Jan. 4, 2024.

(51) Int. Cl. H01L 29/66; H01L 29/06; H01L 29/423; H01L 29/775

(52) U.S. Cl. CPC H10D 64/017; H10D 30/014; H10D 30/43; H10D 30/6735; H10D 62/121

(57) ABSTRACT

A method for forming a semiconductor structure is provided. The method includes forming a fin structure in which first semiconductor layers and second semiconductor layers are alternately stacked over a fin element, forming an isolation structure to surround the fin element, forming a dummy gate dielectric layer across the fin structure over the isolation structure, forming a dummy gate electrode layer on the dummy gate dielectric layer, partially etching the dummy gate electrode layer and the dummy gate dielectric layer to form a trench, removing the first semiconductor layers to form gaps, forming a gate stack on the remaining portion of the dummy gate electrode layer and filling the trench and the gaps.

### PRIORITY CLAIM

This application claims the benefit of U.S. Provisional Application No. 63/617,504, filed on Jan. 4, 2024 and entitled “Semiconductor device and Method for forming the same,” which is incorporated herein by reference.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure, which can extend around the channel region and provide access to the channel on two or four sides. GAA devices are compatible with related complementary metal-oxide-semiconductor (CMOS) processes, and their structure allows them to be aggressively scaled-down while maintaining gate control and mitigating SCEs. In related processes, GAA devices provide a channel in a silicon nanowire. However, integration of fabrication of the GAA features around the nanowire can be challenging. For example, while current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIG. 2 is a layout of a semiconductor structure, in accordance with some embodiments.

FIGS. 3A-1, 3B-1, 3C-1, 3D-1, 3E-1, 3F-1, 3G-1, 3H-1 and 3I-1 are cross-sectional views illustrating the formation of a semiconductor structure at various intermediate stages, in accordance with some embodiments of the disclosure.

FIGS. 3A-2, 3B-2, 3C-2, 3D-2, 3E-2, 3F-2, 3G-2, 3H-2 and 3I-2 are cross-sectional views illustrating the formation of a semiconductor structure at various intermediate stages, in accordance with some embodiments of the disclosure.

FIGS. 3A-3, 3B-3, 3C-3, 3D-3, 3E-3, 3F-3, 3G-3, 3H-3 and 3I-3 are cross-sectional views illustrating the formation of a semiconductor structure at various intermediate stages, in accordance with some embodiments of the disclosure.

FIG. 3I-4 is a plan view illustrating the semiconductor structure at an intermediate stage, in accordance with some embodiments of the disclosure.

FIGS. 4A to 4C are cross-sectional views illustrating the formation of a semiconductor structure at various intermediate stages, in accordance with some embodiments of the disclosure.

FIG. 5 is a modification of the semiconductor structure of FIG. 3I-3, in accordance with some embodiments of the disclosure.

FIG. 6-1 is a modification of the semiconductor structure of FIG. 5, in accordance with some embodiments of the disclosure.

FIG. 6-2 is a plan view illustrating the semiconductor structure at an intermediate stage, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The nanostructure transistor (e.g., nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of a semiconductor structure and a method for forming the semiconductor structure are provided. The method for forming the semiconductor structure includes forming a dummy gate structure across an active region and an isolation structure, partially etching the gate structure to leave the remaining portion on the isolation structure, and forming a gate stack on the remaining dummy gate structure. The remaining dummy gate structure may prevent or mitigate the loss of the isolation structure. Therefore, the performance of the resulting semiconductor device may be improved, in accordance with some embodiments.

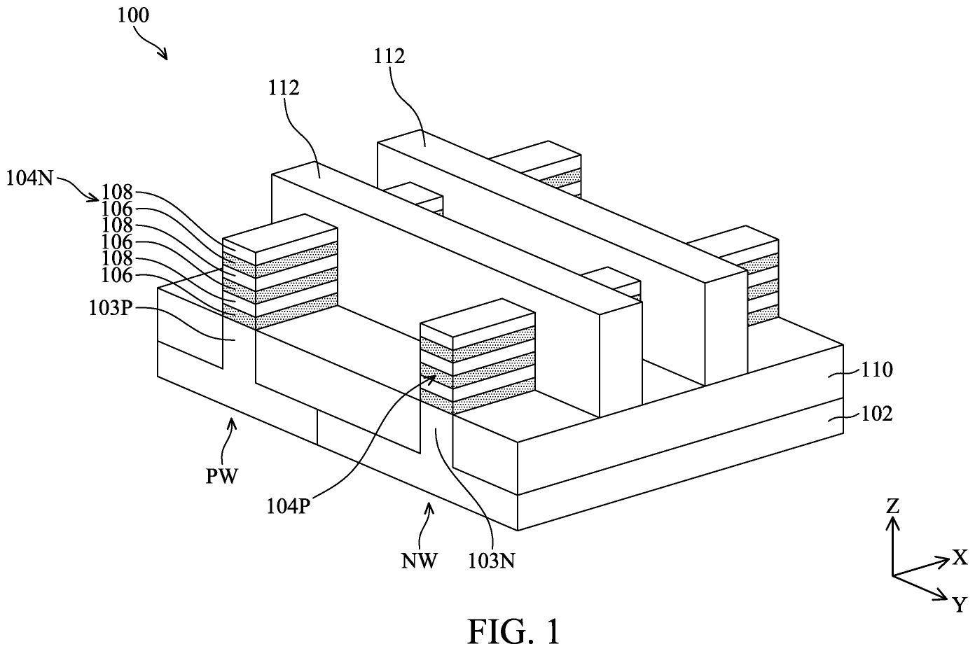

FIG. 1 is a perspective view of a semiconductor structure 100, in accordance with some embodiments.

The semiconductor structure 100 includes a substrate 102 and fin structures 104 (including 104N and 104P) over the substrate 102, as shown in FIG. 1, in accordance with some embodiments. The substrate 102 includes a p-type well PW and an n-type well NW immediately adjacent to the p-type well PW, in accordance with some embodiments. The fin structure 104N is formed in the p-type well PW, and the fin structure 104P is formed in the n-type well NW, in accordance with some embodiments. The fin structures 104N and 104P are the active regions of the semiconductor structure 100, in accordance with some embodiments.

For a better understanding of the semiconductor structure 100, the X-Y-Z coordinate reference is provided in the figures of the present disclosure. The X-axis and the Y-axis are generally orientated along the lateral (or horizontal) directions that are parallel to the main surface of the substrate 102. The Y-axis is transverse (e.g., substantially perpendicular) to the X-axis. The Z-axis is generally oriented along the vertical direction that is perpendicular to the main surface of the substrate 102 (or the X-Y plane).

The fin structure 104N includes a lower fin element 103P formed from the p-type well PW, and the fin structure 104P includes a lower fin element 103N formed from the n-type well NW, in accordance with some embodiments. The lower fin elements 103P and 103N are surrounded by an isolation structure 110, in accordance with some embodiments.

Each of the fin structures 104N and 104P further includes an upper fin element formed from an epitaxial stack including alternating first semiconductor layers 106 and second semiconductor layers 108, in accordance with some embodiments. The second semiconductor layers 108 will form nanostructures (e.g., nanowires or nanosheets) and serve as the channel for the resulting semiconductor devices, in accordance with some embodiments.

The fin structures 104 extend in the X direction, in accordance with some embodiments. That is, the fin structures 104 have longitudinal axes parallel to the X direction, in accordance with some embodiments. The X direction may also be referred to as the channel-extending direction. The current of the resulting semiconductor device (i.e., nanostructure transistor) flows in the X direction through the channel. Each of the fin structures 104 is defined as several channel regions and several source/drain regions, where the channel regions and the source/drain regions are arranged in an alternating manner, in accordance with some embodiments. In this disclosure, a source/drain refers to a source and/or a drain. It should be noted that source and drain are used interchangeably in the present disclosure, and the structures thereof are substantially the same.

Gate structures 112 are formed with longitudinal axes parallel to the Y direction and extending across and/or surrounding the channel regions of the fin structures 104N and 104P, in accordance with some embodiments. The source/drain regions of the fin structures 104N and 104P are exposed from the gate structures 112, in accordance with some embodiments. The Y direction may also be referred to as a gate-extending direction.

Although two fin structures 104 and two gate structures 112 are illustrated in FIG. 1, the semiconductor structure 100 is not intended to be limiting. The number of fin structures and the gate structures may be dependent on the design demand of an integrated circuit and/or performance consideration of resulting semiconductor devices.

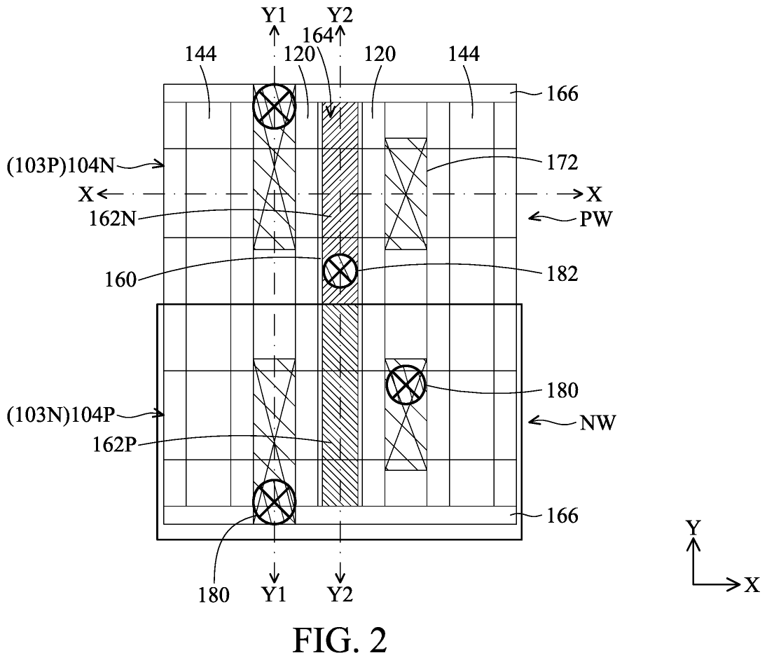

FIG. 2 is a layout of a semiconductor structure 100, in accordance with some embodiments.

The semiconductor structure 100 may be or include nanostructure devices (e.g., GAA FETs), in accordance with some embodiments. The semiconductor structure 100 includes active regions 104 (including 104N and 104P) over a substrate (as shown in FIG. 1), and a final gate stack 164 across the active regions 104, in accordance with some embodiments. The substrate includes a p-type well PW and an n-type well NW, in accordance with some embodiments. The p-type well PW and the n-type well NW are immediately arranged in the Y direction, in accordance with some embodiments. The active region 104N is located on the p-type well PW, and the active region 104P is located on the n-type well NW, in accordance with some embodiments.

Each of the active regions 104 includes a lower fin element 103N (or 103P) and nanostructures (not shown in FIG. 2) formed over the lower element 103N (or 103P), in accordance with some embodiments. The final gate stack 164 extends in the Y direction across the lower fin element 103N and 103P, in accordance with some embodiments. The final gate stack 164 wraps around the nanostructures of the active regions 104N and 104P.

In some embodiments, the final gate stack 164 includes a gate dielectric layer 160 and work function metal materials 162 (including 162N and 162P). The work function metal material 162N is formed in the p-type well PW, and the work function metal material 162P is formed in the n-type well NW, in accordance with some embodiments. Gate spacer layers 120 are formed along the opposite sides of the final gate stack 164, in accordance with some embodiments.

The final gate stack 164 is combined with the nanostructures of the active regions 104N and 104P to form nanostructure transistors, in accordance with some embodiments. The nanostructure transistors which are formed over the p-type well PW are n-channel devices (e.g., n-channel nanostructure transistors), and the nanostructure transistors which are formed over the n-type well NW are p-channel devices (e.g., p-channel nanostructure transistors).

Fin isolation structures 144 extend in the Y direction, cut through active regions 104, in accordance with some embodiments. In some embodiments, the fin isolation structures 144 are formed by replacing the gate structures with dielectric material. Gate spacer layers 120 are also formed along the opposite sides of the fin isolation structures 144, in accordance with some embodiments.

Gate isolation structures 166 extend in the X direction and cut through the final gate stack 164 and the gate spacer layers 120, in accordance with some embodiments. The gate isolation structures 166 and the fin isolation structures 144 may be configured to collectively define a cell region in which a functional circuit is formed (e.g., invert circuit, NAND circuit, NOR circuit, etc.). For example, the gate isolation structures 166 are located on the boundaries of a cell with respect to the Y direction, and the fin isolation structures 144 may be located on the boundaries of the cell with respect to the X direction, in accordance with some embodiments.

Contact plugs 172 are formed over the source/drain regions of the active regions 104N and 104P, in accordance with some embodiments. The contact plugs 172 are electrically connected to the source or drain terminals of the nanostructure transistors, in accordance with some embodiments. Vias 180 are formed on and electrically connected to the contact plugs 172, in accordance with some embodiments. A Via 182 is formed on and electrically connected to the work function metal material 162N or 162P of the final gate stack 164, in accordance with some embodiments.

FIG. 2 further illustrates reference cross-sections that are used in later figures. Cross-section X-X is in a plane parallel to the longitudinal axis (X direction) of the fin structure 104N and through the fin structure 104N, in accordance with some embodiments. Cross-section Y1-Y1 is in a plane parallel to the longitudinal axis (Y direction) of the final gate stack 164 and across the source/drain regions of the fin structures 104, in accordance with some embodiments. Cross-section Y2-Y2 is in a plane parallel to the longitudinal axis (Y direction) of the final gate stack 164 and through the final gate stack 164 (or a dummy gate structure), in accordance with some embodiments.

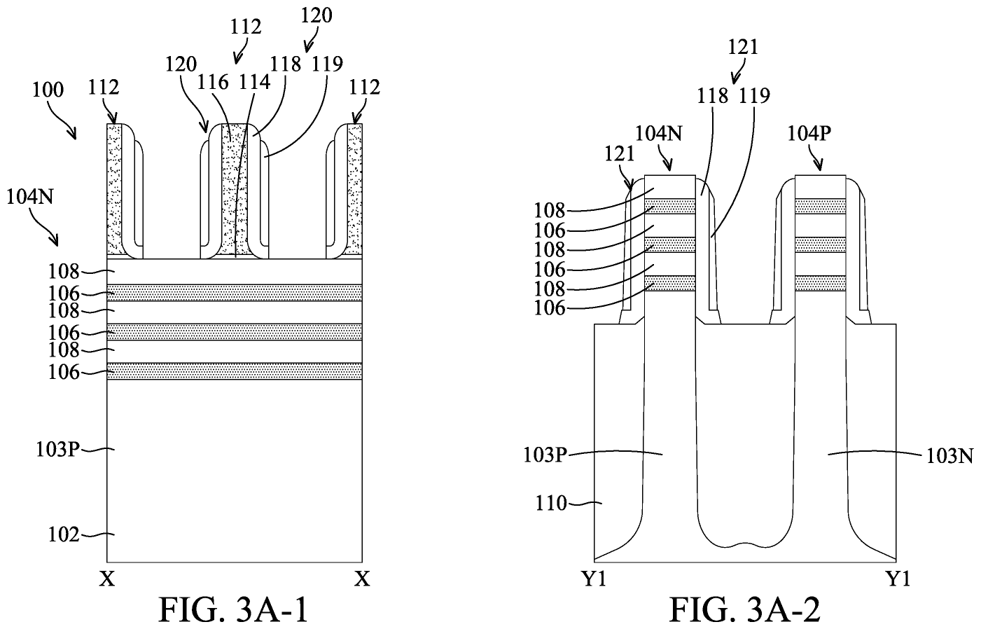

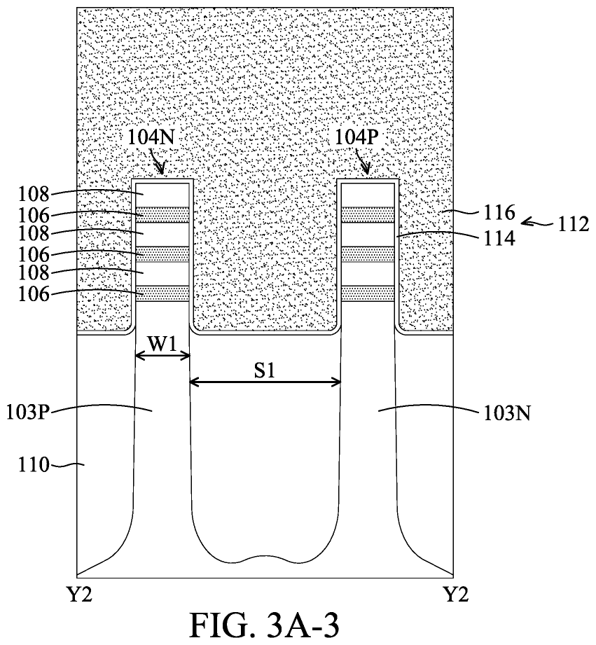

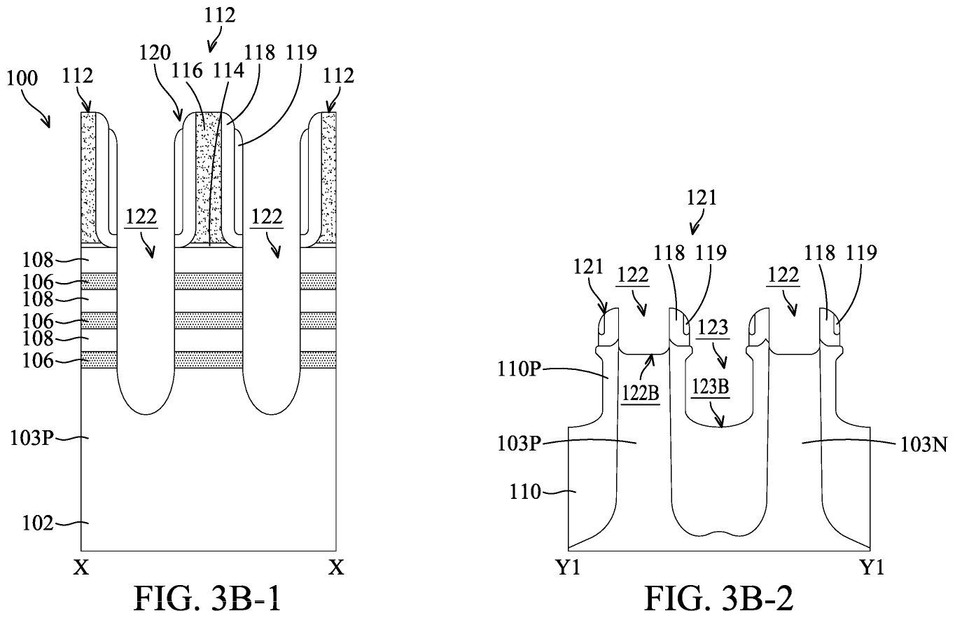

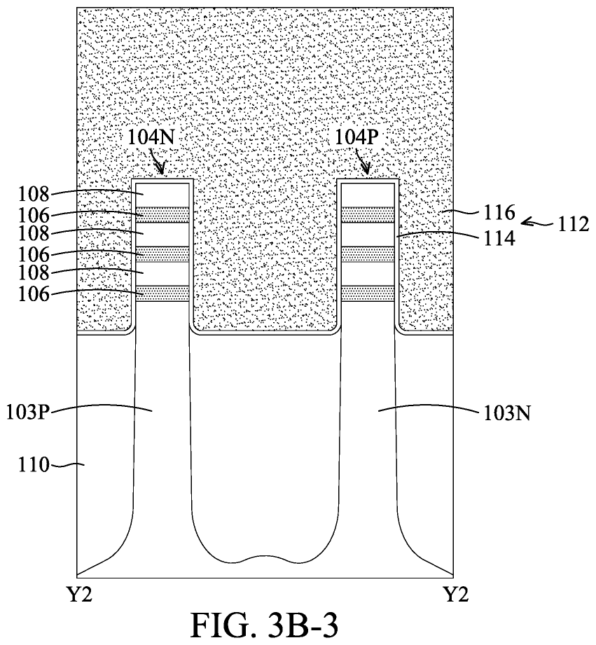

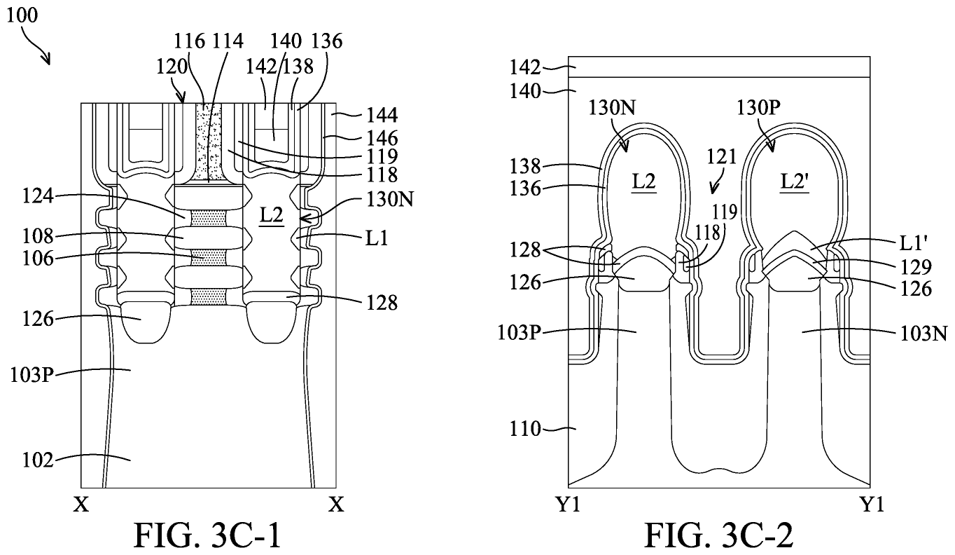

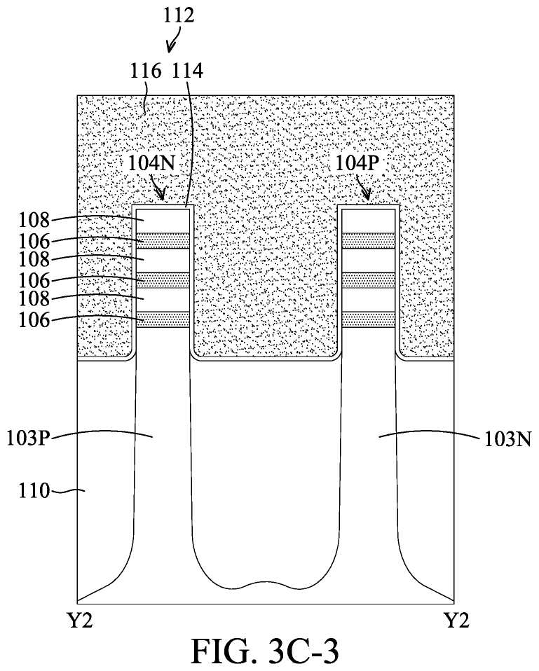

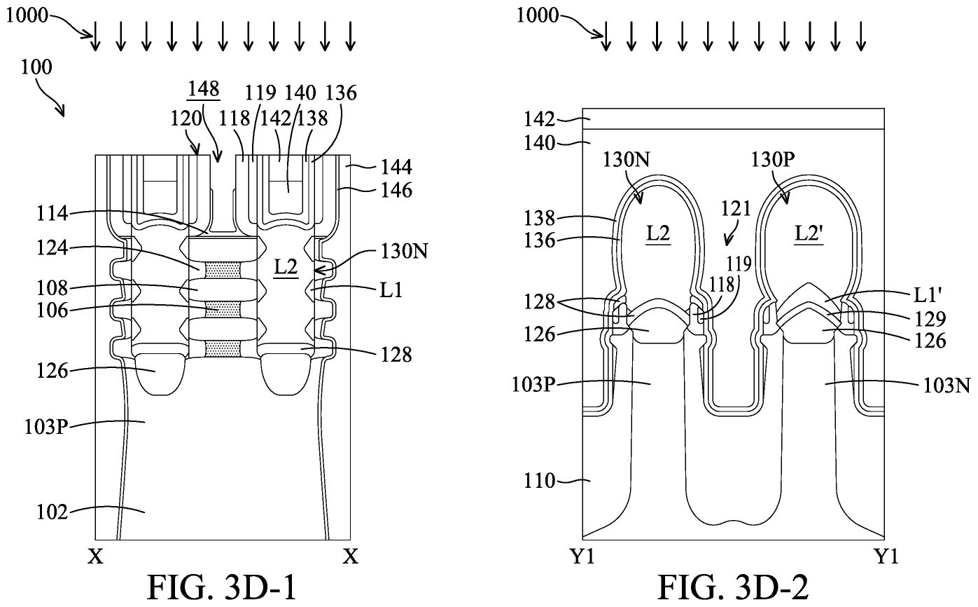

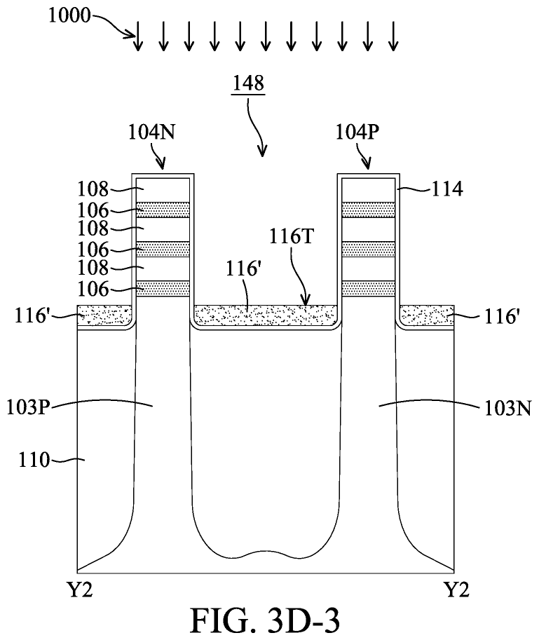

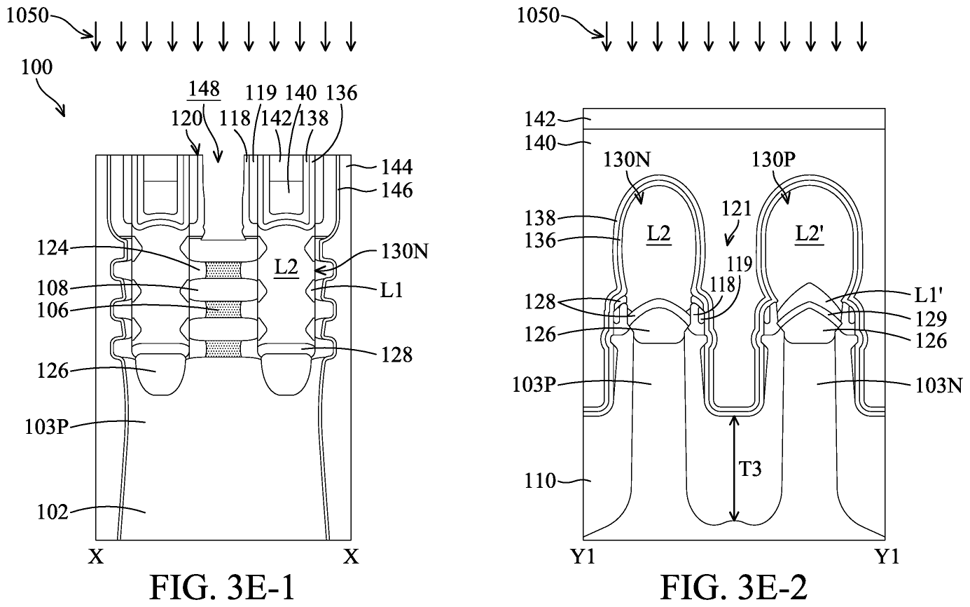

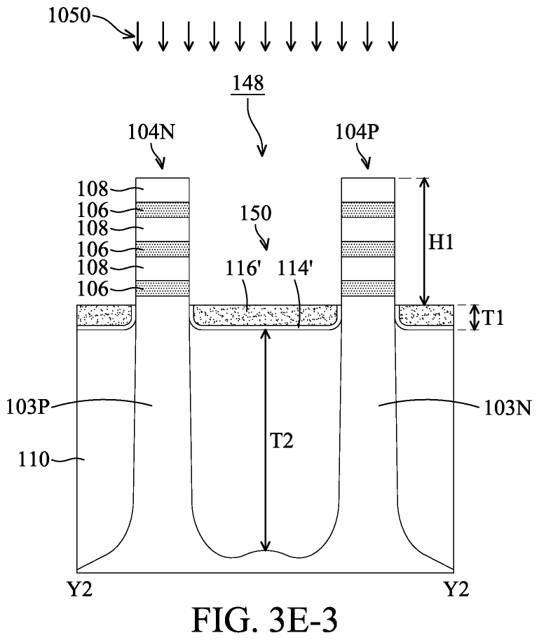

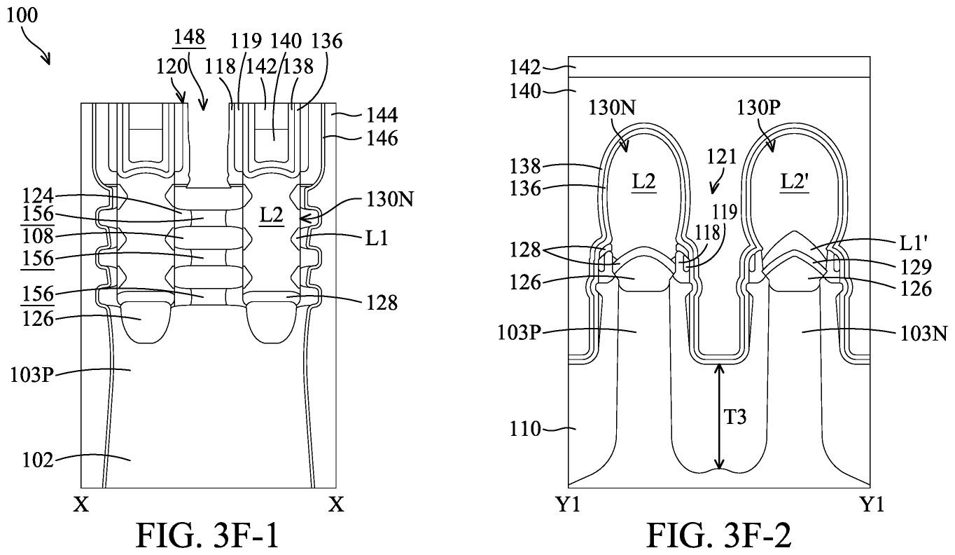

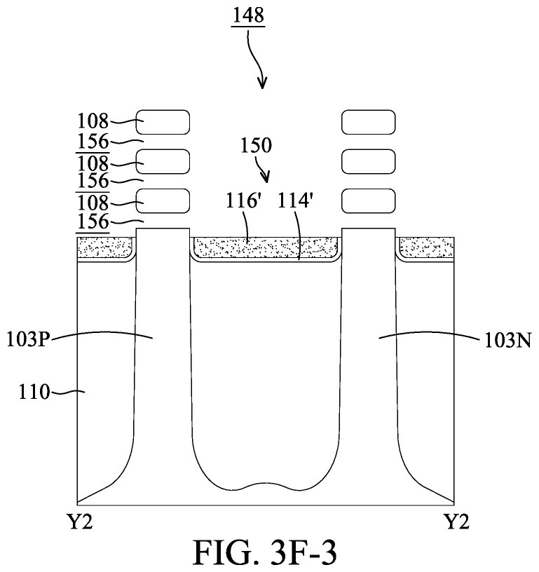

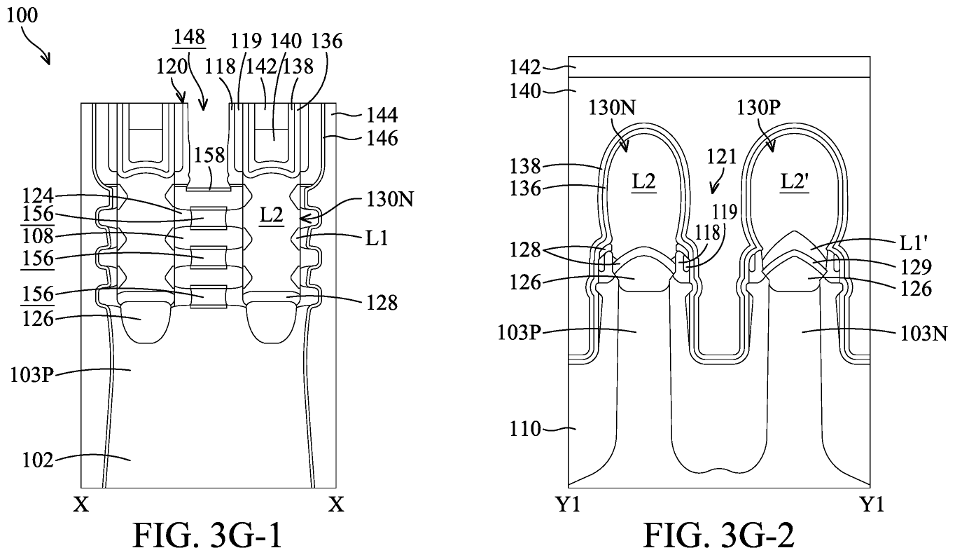

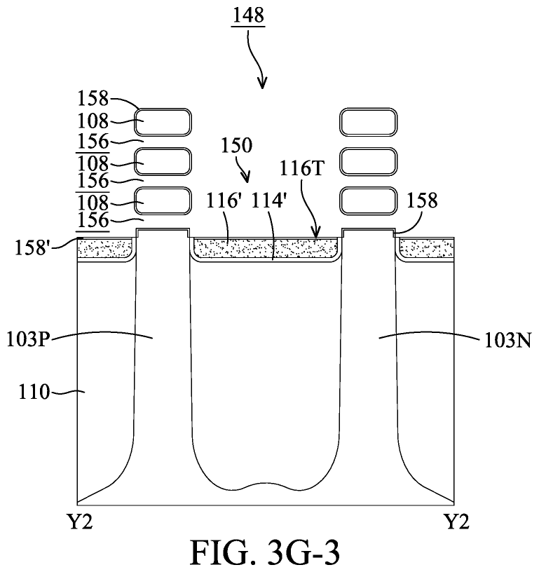

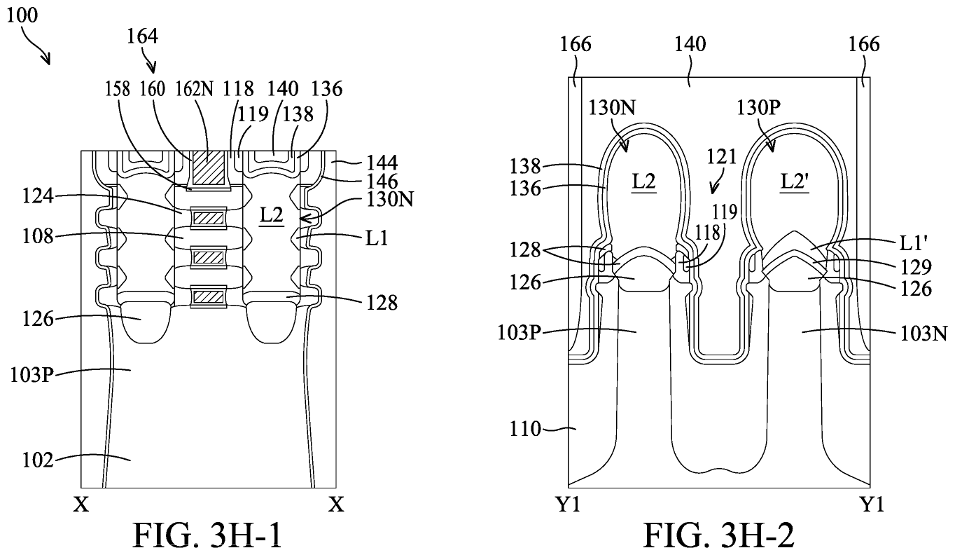

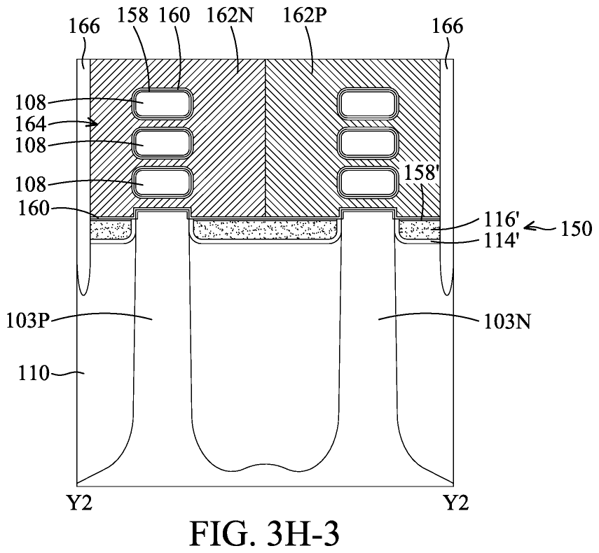

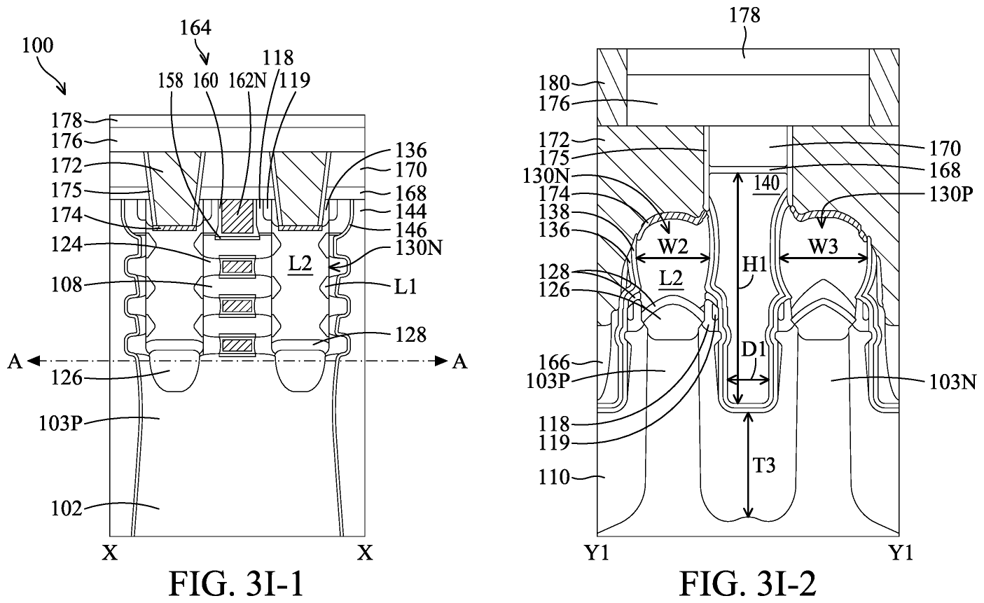

FIGS. 3A-1 through 3I-3 are cross-sectional views illustrating the formation of a semiconductor structure 100 at various intermediate stages, in which FIGS. 3A-1, 3B-1, 3C-1, 3D-1, 3E-1, 3F-1, 3G-1, 3H-1 and 3I-1 correspond to cross-section X-X shown in FIG. 2, FIGS. 3A-2, 3B-2, 3C-2, 3D-2, 3E-2, 3F-2, 3G-2, 3H-2 and 3I-2 correspond to cross-section Y1-Y1 shown in FIG. 2, and FIGS. 3A-3, 3B-3, 3C-3, 3D-3, 3E-3, 3F-3, 3G-3, 3H-3 and 3I-3 correspond to cross-section Y2-Y2 shown in FIG. 2, in accordance with some embodiments of the disclosure.

FIGS. 3A-1 to 3A-3 illustrate a semiconductor structure 100 after the formation of active regions 104, an isolation structure 110, dummy gate structures 112, gate spacer layers 120 and fin spacer layers 121, in accordance with some embodiments.

A substrate 102 is provided, as shown in FIGS. 3A-1 to 3A-3, in accordance with some embodiments. The substrate 102 may be a portion of a semiconductor wafer, a semiconductor chip (or die), and the like. In some embodiments, the substrate 102 is a silicon substrate. In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

An N-type well and a p-type well (as shown in FIGS. 1 and 2) are formed in the substrate 102, in accordance with some embodiments. In some embodiments, the n-type well and the p-type well have different electrically conductive types. In some embodiments, the wells NW and PW are formed by respective ion implantation processes. In some embodiments, the ion implantation processes may be performed several times with different dosages and different energy intensities. In some embodiments, the ion implantation process may include anti-punch through (APT) implant.

Active regions 104 (including 104N and 104P) are formed over the substrate 102, as shown in FIGS. 3A-1 to 3A-3, in accordance with some embodiments. In some embodiments, the active regions 104N and 104P extend in the X direction. In some embodiments, the active regions 104N and 104P are the fin structures 104N and 104P as shown in FIG. 1.

The formation of the active regions 104N and 104P includes forming an epitaxial stack over the substrate 102 using an epitaxial growth process, in accordance with some embodiments. The epitaxial stack includes alternating first semiconductor layers 106 and second semiconductor layers 108, in accordance with some embodiments. The epitaxial growth process may be molecular beam epitaxy (MBE), metal organic chemical vapor deposition (MOCVD), or vapor phase epitaxy (VPE), or another suitable technique.

In some embodiments, the first semiconductor layers 106 are made of a first semiconductor material and the second semiconductor layers 108 are made of a second semiconductor material. The first semiconductor material for the first semiconductor layers 106 has a different lattice constant than the second semiconductor material for the second semiconductor layers 108, in accordance with some embodiments. In some embodiments, the first semiconductor material and the second semiconductor material have different oxidation rates and/or etching selectivity. In some embodiments, the first semiconductor layers 106 are made of SiGe, where the percentage of germanium (Ge) in the SiGe is in a range from about 20 atomic % to about 50 atomic %, and the second semiconductor layers 108 are made of pure or substantially pure silicon. In some embodiments, the first semiconductor layers 106 are Si₁₋ₓGeₓ, where x is more than about 0.3, or Ge (x=1.0) and the second semiconductor layers 108 are Si or Si_{1-y}Ge_{y}, where y is less than about 0.4, and x>y.

The first semiconductor layers 106 are configured as sacrificial layers and will be removed to form gaps to accommodate gate materials, and the second semiconductor layers 108 will form nanostructures (e.g., nanowires or nanosheets) that laterally extend between source/drain features and serve as the channel for the resulting semiconductor devices (such as nanostructure transistors), in accordance with some embodiments.

The formation of the active regions 104N and 104P further includes patterning the epitaxial stack and underlying wells (e.g., PW and NW shown in FIGS. 1 and 2) using photolithography and etching processes, thereby forming trenches, in accordance with some embodiments. The active regions 104N and 104P protrude from between trenches, in accordance with some embodiments.

The p-type well protruding from between the trenches forms the lower fin element 103P of the active region 104N, and the n-type well protruding from between the trenches forms the lower fin element 103N of the active region 104P, in accordance with some embodiments. The remainder of the epitaxial stack (including the semiconductor layers 106 and 108) forms the upper fin elements of the active regions 104N and 104P, in accordance with some embodiments.

In some embodiments, the thickness of each of the first semiconductor layers 106 is in a range from about 3 nm to about 20 nm, such as about 4 nm to about 12 nm. In some embodiments, the thickness of each of the second semiconductor layers 108 is in a range from about 3 nm to about 20 nm, such as about 4 nm to about 12 nm. The thickness of the second semiconductor layers 108 may be greater than, equal to, or less than the first semiconductor layers 106, which may depend on the amount of gate materials to be filled in spaces where the first semiconductor layers 106 are removed.

In some embodiments, the active regions 104 have a width W1 in a range from about 15 nm to about 25 nm. In some embodiments, the spacing S1 between the active region 104N and the active region 104P is in a range from about 25 nm to about 35 nm.

An isolation structure 110 is formed to surround the lower fin elements 103N and 103P, as shown in FIGS. 3A-2 and 3A-3, in accordance with some embodiments. The isolation structure 110 is configured to electrically isolate active regions 104 from one another, and is also referred to as shallow trench isolation (STI) feature, in accordance with some embodiments.

The formation of the isolation structure 110 includes forming an insulating material to overfill the trenches, in accordance with some embodiments. In some embodiments, the insulating material is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof. In some embodiments, the insulating material is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

A planarization process (e.g., chemical mechanical polishing (CMP), etching back process, or a combination thereof) is performed on the insulating material, in accordance with some embodiments. The insulating material is then recessed by an etching process (such as dry plasma etching and/or wet chemical etching) until the upper fin elements of the active regions 104 are exposed, in accordance with some embodiments. The top portions of the lower fin element 103N and 104P may be further exposed from the isolation structure 110, in accordance with some embodiments.

Dummy gate structures 112 are formed across the active regions 104 and the isolation structure 110, as shown in FIGS. 3A-1 and 3A-3, in accordance with some embodiments. The dummy gate structures 112 are configured as sacrificial structures and will be replaced with the final gate stacks, in accordance with some embodiments. In some embodiments, the dummy gate structures 112 extend in the Y direction. The dummy gate structures 112 surround the channel regions of the active regions 104, in accordance with some embodiments. The dummy gate structures 112 are the gate structures 112 shown in FIG. 1.

Each of the dummy gate structures 112 includes a dummy gate dielectric layer 114 and a dummy gate electrode layer 116 over the dummy gate dielectric layer, in accordance with some embodiments. In some embodiments, the dummy gate dielectric layer 114 is conformally formed along the upper fin elements of the active regions 104 using ALD, CVD, thermal oxidation, physical vapor deposition (PVD), another suitable technique, or a combination thereof. In some embodiments, the dummy gate dielectric layer 114 is made of one or more dielectric materials, such as silicon oxide (SiO), silicon nitride (SiN), silicon oxynitride (SiON), HfO₂, HfZrO, HfSiO, HTIO, HfAlO

In some embodiments, the dummy gate electrode layer 116 is made of semiconductor material such as polysilicon or poly-silicon germanium. In some embodiments, the material for the dummy gate electrode layer 116 is deposited using CVD, ALD, another suitable technique, or a combination thereof. Once the material for the dummy gate electrode layer 116 is deposited, the material for the dummy gate electrode layer 116 is planarized, and the material for the dummy gate electrode layer 116 and the dielectric material are patterned into the dummy gate structures 112 using photolithography and etching processes.

Gate spacer layers 120 are formed along opposite sidewalls of the dummy gate structures 112, and fin spacer layers 121 are formed along opposite sidewalls of the active regions 104, as shown in FIGS. 3A-1 and 3A-2, in accordance with some embodiments. The gate spacer layers 120 extend in the Y direction and across the active regions 104 and the isolation structure 110, in accordance with some embodiments. The gate spacer layers 120 are used to offset the subsequently formed source/drain features and separate the source/drain features from the gate structure, in accordance with some embodiments. The fin spacer layers 121 extend in the X direction, in accordance with some embodiments. The fin spacer layers 121 are used to confine the growth of epitaxial material to prevent neighboring epitaxial material from merging with each other, in accordance with some embodiments.

In some embodiments, the gate spacer layers 120 and the fin spacer layers 121 are formed from one or more continuous dielectric material(s). For example, in some embodiments, the formation of the gate spacer layers 120 and the fin spacer layers 121 includes globally and conformally depositing spacer layers 118 and 119 over the semiconductor structure 100 using ALD, CVD (such as LPCVD, PECVD or HDP-CVD or a combination thereof, followed by an anisotropic etching process, as shown in FIGS. 3A-2 and 3A-3, in accordance with some embodiments.

In some embodiments, the spacer layers 118 and 119 are made of a dielectric material, such as silicon nitride (SiN), silicon oxynitride (SiON), silicon oxide (SiO₂), oxygen-doped silicon carbide (SiC:O), oxygen-doped silicon carbonitride (Si(O)CN), silicon carbide (SiC), or another suitable dielectric material. In some embodiments, the spacer layer 118 and the spacer layer 119 are made of different materials and have different dielectric constant values. For example, the spacer layers 118 and 119 are made of SiOCN with different compositions (e.g., different carbon concentrations) and different dielectric constants. In some other embodiments, the spacer layers 118 and 119 are the same material.

After the anisotropic etching process, the vertical portions of the spacer layers 118 and 119 left remaining on the opposite sides of the dummy gate structures 112 form the gate spacer layers 120, in accordance with some embodiments. The vertical portions of the spacer layers 118 and 119 left remaining on the opposite sides of the active regions 104 form the fin spacer layers 121, in accordance with some embodiments.

FIGS. 3B-1 to 3B-3 illustrate a semiconductor structure 100 after the formation of source/drain recess 122, in accordance with some embodiments.

An etching process is performed to recess the source/drain regions of the active regions 104N and 104P, thereby forming source/drain recesses 122, as shown in FIGS. 3B-1 and 3B-2, in accordance with some embodiments. The etching process may be an anisotropic etching process such as dry plasma etching, an isotropic etching process such as dry chemical etching, remote plasma etching or wet chemical etching, and/or a combination thereof. The gate spacer layers 120 and the dummy gate structures 112 may serve as etch masks such that the source/drain recesses 122 are formed self-aligned on opposite sides of the dummy gate structures 112, in accordance with some embodiments.

The bottom 122B of the source/drain recess 122 extends into the lower fin elements 103N and 103P, in accordance with some embodiments. The bottoms 122B of the source/drain recesses 122 may be a curved surface (e.g., convex surface), in accordance with some embodiments.

In the etching process, the isolation structure 110 is also recessed, thereby forming STI recesses 123, as shown in FIG. 3B-2, in accordance with some embodiments. In some embodiments, the bottom 123B of the STI recess 123 extends downward to a deeper position than the bottom 122B of the source/drain recess 122. The bottom 123B of the STI recesses 123 may be a curved surface (e.g., convex surface), in accordance with some embodiments.

The fin spacer layers 121 are also recessed in the etching process, in accordance with some embodiments. In some embodiments, after the etching process, the isolation structure 110 includes a protruding portion 110P directly under the fin spacer layers 121 and between the lower fin element 103N (or 103P) and the STI recess 123.

FIGS. 3C-1 to 3C-3 illustrate a semiconductor structure 100 after the formation of inner spacers 124, semiconductor isolation layers 126 and 129, dielectric isolation layers 128, source/drain features 130N and 130P, and fin isolation structures 144, in accordance with some embodiments.

An etching process is performed to laterally recess, from the source/drain recesses 122, the first semiconductor layers 106 of the active regions 104, thereby forming notches, and then inner spacer layers 124 are formed in the notches, as shown in FIG. 3C-1, in accordance with some embodiments. The inner spacer layers 124 abut the recessed side surfaces of the first semiconductor layers 106, in accordance with some embodiments. The inner spacer layers 124 may avoid the source/drain features and the gate stack from being in direct contact and are configured to reduce the parasitic capacitance between the gate stack and the source/drain features (i.e., Cgs and Cgd), in accordance with some embodiments.

In some embodiments, the inner spacer layers 124 are made of dielectric material, such as silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), and/or a combination thereof. In some embodiments, the inner spacer layers 124 are formed by depositing a dielectric material to fill the notches using ALD, CVD (such as PECVD, LPCVD or HARP), another suitable technique, or a combination thereof, and the dielectric material outside the notches are then etched away using an anisotropic etching process such as dry plasma etching, an isotropic etching process such as dry chemical etching, remote plasma etching or wet chemical etching, or a combination thereof.

Semiconductor isolation layers 126 are grown on the lower fin elements 103N and 103P, as shown in FIGS. 3C-1 and 3C-2, in accordance with some embodiments. In some embodiments, the semiconductor isolation layers 126 are made of an epitaxial semiconductor material such as silicon, silicon germanium or germanium, formed by MBE, MOCVD, or VPE, another suitable technique, or a combination thereof. In an embodiment, the semiconductor isolation layers 126 are made of non-doped silicon.

Dielectric isolation layers 128 are formed on the semiconductor isolation layers 126 on the lower fin elements 103P (in the p-type well), as shown in FIGS. 3C-1 and 3C-2, in accordance with some embodiments. In some embodiments, the dielectric isolation layers 128 are made of dielectric material silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN).

In some embodiments, the dielectric isolation layers 128 are formed by forming a patterned mask layer (not shown) to cover the semiconductor structure 100 in the n-type well, followed by deposition and etching-back processes. After the etching-back processes, the dielectric isolation layers 128 may remain on the fin spacer layers 121, as shown in FIG. 3C-2, in accordance with some embodiments.

The source/drain features 130N are grown from the exposed side surfaces of the second semiconductor layers 108 in the p-type well using an epitaxial growth process, as shown in FIGS. 3C-1 and 3C-2, in accordance with some embodiments. The epitaxial growth process may be MBE, MOCVD, or VPE, or another suitable technique.

In some embodiments, the source/drain features 130N are made of semiconductor epitaxial material such as SiP, SiAs, SiCP, SiC, Si, GaAs, another suitable semiconductor material, or a combination thereof. In some embodiments, the source/drain features 130 are doped with the n-type dopant during the epitaxial growth process. For example, the n-type dopant may be phosphorous (P) or arsenic (As). For example, the source/drain features 130N may be the epitaxially grown Si doped with phosphorous to form silicon:phosphor (Si:P) source/drain features and/or arsenic to form silicon:arsenic (Si:As) source/drain feature.

In some embodiments, the source/drain features 130N may be multilayered structures, e.g., including sequentially formed epitaxial layers L1 and L2. In some embodiments, the concentration of the dopant in the epitaxial layer L2 is higher than the concentration of the dopant in the epitaxial layer L1, e.g., by 1-2 orders.

Afterward, the patterned mask layer which covers the semiconductor structure 100 in the n-type well may be removed, and another patterned mask layer (not shown) is formed to cover the semiconductor structure 100 in the p-type well.

Semiconductor isolation layer 129 is grown on the lower fin elements 103N, as shown in FIG. 3C-2, in accordance with some embodiments. In some embodiments, the semiconductor isolation layers 129 is made of silicon germanium with low germanium concentration.

The source/drain features 130P are grown from the exposed side surfaces of the second semiconductor layers 108 in the n-type well using an epitaxial growth process, as shown in FIG. 3C-2, in accordance with some embodiments. The epitaxial growth process may be MBE, MOCVD, or VPE, or another suitable technique.

The source/drain features 130P are made of semiconductor material such as SiGe, Si, GaAs, another suitable semiconductor material, or a combination thereof. In some embodiments, the source/drain features 130P are doped with the p-type dopant during the epitaxial growth process. For example, the p-type dopant may be boron (B) or BF₂. For example, the source/drain features 130 may be the epitaxially grown SiGe doped with boron (B) to form silicon germanium:boron (SiGe:B) source/drain feature.

In some embodiments, the source/drain features 130P may be multilayered structures, e.g., including sequentially formed epitaxial layers L1′ and L2′. In some embodiments, the concentration of the dopant in the epitaxial layer L2′ is higher than the concentration of the dopant in the epitaxial layer L1′, e.g., by 1-2 orders.

Contact etching stop layers 136 and 138 are sequentially formed over the semiconductor structure 100 to cover the source/drain features 130N and 130P, as shown in FIGS. 3C-1 and 3C-2, in accordance with some embodiments. In some embodiments, the contact etching stop layers 136 and 138 are made of a dielectric material, such as silicon nitride (SiN), silicon oxynitride (SiON), silicon oxide (SiO₂), oxygen-doped silicon carbide (SiC:O), oxygen-doped silicon carbonitride (Si(O)CN), silicon carbide (SiC), or another suitable dielectric material.

In some embodiments, the contact etching stop layers 136 and 138 are globally and conformally deposited using ALD, CVD (such as LPCVD, PECVD, HDP-CVD and HARP), another suitable method, and/or a combination thereof. In some embodiments, the contact etching stop layers 136 and 138 are made of different materials and have different dielectric constant values. For example, the contact etching stop layer 136 is a SiON layer and the contact etching stop layer 138 is a SiN layer.

A first interlayer dielectric layer 140 is formed over the contact etching stop layer 138, as shown in FIGS. 3C-1 and 3C-2, in accordance with some embodiments. The first interlayer dielectric layer 140 overfills the space between dummy gate structures 112, in accordance with some embodiments. In some embodiments, the first interlayer dielectric layer 140 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material.

In some embodiments, the dielectric material for the first interlayer dielectric layer 140 is deposited using such as CVD (such as HDP-CVD, PECVD, HARP or FCVD), another suitable technique, or a combination thereof. The dielectric materials for the contact etching stop layers 136 and 138 and the first interlayer dielectric layer 140 above the top surface of the dummy gate electrode layer 116 are removed using such as CMP, in accordance with some embodiments.

Afterward, the first interlayer dielectric layer 140 is recessed to form trenches (now shown), and a dielectric mask layer 142 is formed to fill the trenches, as shown in FIGS. 3C-1 and 3C-2. The dielectric mask layer 142 is configured to protect the first interlayer dielectric layer 140 in the following etching processes, and may have a different etching selectivity than the first interlayer dielectric layer 140, in accordance with some embodiments.

In some embodiments, the dielectric mask layer 142 is made of a dielectric material, such as silicon nitride (SiN), silicon oxynitride (SiON), silicon oxide (SiO₂), oxygen-doped silicon carbide (SiC:O), oxygen-doped silicon carbonitride (Si(O)CN), silicon carbide (SiC), or another suitable dielectric material. In some embodiments, the formation of the dielectric mask layer 142 includes a deposition process, followed by a removal process (e.g., etching-back or CMP process).

Some of the dummy gate structures 112 are replaced with fin isolation structures 144, as shown in FIG. 3C-1, in accordance with some embodiments. The fin isolation structures 144 are formed to penetrate through the dummy gate structures 112 and the underlying active regions 104N and 104P, in accordance with some embodiments. In some embodiments, the fin isolation structures 144 extend in the Y direction. In some embodiments, the fin isolation structures 144 are configured to prevent leakage between the neighboring cell regions. The fin isolation structures 144 may be also referred to as cut poly gate on oxide definition edge (CPODE) pattern.

The fin isolation structures 144 are made of a dielectric material such as silicon oxide (SiO₂), silicon oxynitride (SiON), silicon nitride (SiN), silicon carbon nitride (SiCN), silicon oxycarbonitride (SiOCN), oxygen-doped silicon carbonitride (Si(O)CN), or a combination thereof. In some embodiments, the fin isolation structures 144 include dielectric material with k-value greater than 7.9, such as LaO, AlO, AlON, ZrO, HfO, ZnO, ZrN, ZrAlO, TiO, TaO, YO, TaCN, or a combination thereof.

The formation of the fin isolation structures 144 includes patterning the dummy gate structures 112 and the active regions 104N and 104P using photolithography and etching processes to form cutting trenches, optionally depositing a dielectric lining layer 146, depositing a dielectric material for the fin isolation structures 144 to overfill the cutting trenches, in accordance with some embodiments. A planarization process (e.g., CMP, etching back process, or a combination thereof) is then performed on dielectric material formed until the first interlayer dielectric layer 140 is exposed, in accordance with some embodiments.

FIGS. 3C-1 to 3D-3 illustrate the formation of gate trenches 148, in accordance with some embodiments.

A first etching process 1000 is performed to recess the dummy gate electrode layer 116, thereby forming gate trenches 148, as shown in FIGS. 3D-1 and 3D-3, in accordance with some embodiments. The dummy gate electrode layer 116 is recessed until the top surface 116T of the dummy gate electrode layer 116 is lower than the top surfaces of the lower fin elements 103N and 103P, as shown FIG. 3D-3, in accordance with some embodiments. In some embodiments, the top surface 116T is a substantially flat surface. In some other embodiments, the top surface 116T is a curve surface.

The first etching process 1000 may be an anisotropic etching process such as dry plasma etching, in accordance with some embodiments. In some embodiments, the first etching process 1000 uses fluorine-containing etchant, e.g., NF₃, F₂, CF₄, SF₆, NF₃, CH₂F₂, CHF₃, or C₂F₆. The first etching process 1000 may be controlled, e.g., by time mode or end-point mode, thereby allowing the remaining dummy gate electrode layer 116′ to have a desirable thickness. The remaining portions 116′ of the dummy gate electrode layer 116 are left on the isolation structure 110, and thus the underlying isolation structure 110 is not recessed in the first etching process 1000, in accordance with some embodiments.

The dummy gate dielectric layer 114 is exposed from the gate trenches 148, in accordance with some embodiments. In the first etching process 1000, the top portions of the dummy gate dielectric layer 114 along the sidewalls of the gate spacer layers 118 are etched away, as shown FIG. 3D-1, in accordance with some embodiments.

A second etching process 1050 is performed to etch away the portion of the dummy gate dielectric layer 114 exposed from the gate trenches 148, as shown in FIGS. 3E-1 and 3E-3, in accordance with some embodiments. The gate trenches 148 are enlarged and expose the gate spacer layers 118 and the upper fin elements of the active regions 104N and 104P, in accordance with some embodiments, in accordance with some embodiments. The second etching process 1050 may be dry plasma etching, a dry chemical etching, and/or a wet etching. in accordance with some embodiments.

In the second etching process 1050, the remaining portions 116′ of the dummy gate electrode layer 116 is substantially or slightly unetched, and the portions 114′ of the dummy gate dielectric layer 114 covered by the dummy gate electrode layer 116′ are left on the isolation structure 110, in accordance with some embodiments. As a result, the isolation structure 110 is not recessed in the second etching process 1050, in accordance with some embodiments.

The remaining portions 114′ of the dummy gate dielectric layer 114 and the remaining portions 116′ of the dummy gate electrode layer 116 are collectively referred to as protection features 150, in accordance with some embodiments. The protection features 150 protect the isolation structure 110 from being recessed, in accordance with some embodiments.

In some embodiments, the protection features 150 have a thickness T1 in a range from about 3 nm to about 5 nm. If the protection feature 150 is thin, the isolation structure 110 may be recessed. If the protection feature 150 is thick, the sidewalls of the bottommost first semiconductor layer 106 may be covered, making it difficult to completely remove the bottommost first semiconductor layer 106 in the subsequent channel release process.

In some embodiments, the exposed portion of the active regions 104N and 104P have a height H1 in a range from about 40 nm to about 45 nm. In some embodiments, the portion of the isolation structure 110 directly under the protection features 150 has a thickness T2 in a range from about 80 nm to about 120 nm. In some embodiments, the portion of the isolation structure 110 directly under the STI recesses 123 (FIG. 3B-2) between the source/drain features 130N/130P has a thickness T3 that is less than the thickness T2.

In some embodiments where the STI recesses 123 are not formed, the thickness T3 of the isolation structure 110 between the source/drain features 130N/130P is substantially the same as the thickness T2 of the isolation structure 110 directly under the protection features 150

FIGS. 3F-1 to 3F-3 illustrate a semiconductor structure 100 after a channel release process, in accordance with some embodiments.

An etching process is performed on the first semiconductor layers 106 of the active regions 104N and 104P to form gaps 156, as shown in FIGS. 3F-1 and 3F-2, in accordance with some embodiments. The inner spacers 124 may be used as an etching stop layer in the etching process, which may protect the source/drain features 130N and 130P from being damaged. In some embodiments, the etching process may be dry chemical etching, remote plasma etching or wet chemical etching. In some embodiments, the gaps 156 expose the sidewalls of the inner spacers 124 facing the channel region. The protection features 150 may protect the isolation structure 110 from being recessed in the channel release process.

The four main surfaces of the second semiconductor layers 108 are exposed, in accordance with some embodiments. The exposed second semiconductor layers 108 form nanostructures, in accordance with some embodiments. The nanostructures 108 are vertically stacked and spaced apart from one other, in accordance with some embodiments. As the term is used herein, “nanostructures” refers to the semiconductor layers with cylindrical shape, bar shaped and/or sheet shape. The nanostructures 108 function as channels of the resulting semiconductor devices (e.g., nanostructure transistors such as GAA transistors), in accordance with some embodiments.

FIGS. 3G-1 to 3G-3 illustrate a semiconductor structure 100 after the formation of an interfacial layer 158, in accordance with some embodiments.

The interfacial layer 158 is formed on the exposed surfaces of the nanostructures 108 and the exposed surfaces of the lower fin elements 103N and 103P, in accordance with some embodiments. The interfacial layer 158 wraps around the nanostructures 108, in accordance with some embodiments. In some embodiments, the interfacial layer 158 is made of a chemically formed silicon oxide. In some embodiments, the interfacial layer 158 is nitrogen-doped silicon oxide.

In some embodiments, the interfacial layer 158 is formed using one or more cleaning processes such as including ozone (03), ammonia hydroxide-hydrogen peroxide-water mixture, and/or hydrochloric acid-hydrogen peroxide-water mixture.

Semiconductor material from the nanostructures 108 and the lower fin elements 103N and 103P is oxidized to form the interfacial layer 158, in accordance with some embodiments.

In the one or more cleaning processes, the semiconductor material from the remaining dummy gate electrode layer 116′ is also oxidized to form an oxide layer 158′, in accordance with some embodiments. The oxide layer 158′ is formed on the top surface 116T of the remaining dummy gate electrode layer 116′, in accordance with some embodiments.

FIGS. 3H-1 to 3H-3 illustrate a semiconductor structure 100 after the formation of a final gate stack 164 and gate isolation structures 166, in accordance with some embodiments.

A gate dielectric layer 160 is formed conformally along the interfacial layer 158 to wrap around the nanostructures 108, in accordance with some embodiments. The gate dielectric layer 160 is further formed along the upper surface of the oxide layer 158′, and the sidewalls of the gate spacer layers 118 and the inner spacer layers 124 facing the channel region, in accordance with some embodiments.

The gate dielectric layer 160 may be a high-k dielectric layer. In some embodiments, the high-k dielectric layer is dielectric material with a high dielectric constant (k value), for example, greater than 9, such as greater than 13. In some embodiments, the high-k dielectric layer includes hafnium oxide (HfO₂), TiO₂, HfZrO, Ta₂O₃, HfSiO₄, ZrO₂, ZrSiO₂, LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba, Sr) TiO₃ (BST), Si₃N₄, oxynitrides (SiON), a combination thereof, or another suitable material. The high-k dielectric layer may be deposited using ALD, PVD, CVD, and/or another suitable technique.

The work function metal material 162 (including 162N and 162P) is formed to fill the remainders of the gate trenches 148 and gaps 156, in accordance with some embodiments. The work function metal material 162N is formed over the p-type well, and the work function metal material 162P is formed over the n-type well, in accordance with some embodiments. In some embodiments, the work function metal materials 162N and 162P collectively function as a metal gate electrode layer. In some embodiments, the work function metal materials 162N and 162P have selected work functions to enhance the device performance (e.g., threshold voltage) for n-channel FETs or p-channel FETs.

In some embodiments, the work function metal materials 162N and 162P are made of more than one conductive material, such as a metal, metal alloy, conductive metal oxide and/or metal nitride, another suitable conductive material, or a combination thereof. For example, the work function metal material 162 is TiN, TaN, TiAl, TiAlN, TaAl, TaAlN, TaAlC, TaCN, WNC, Co, Pt, W, Ti, Ag, Al, TaC, TaSiN, Mn, Zr, Ru, Mo, WN, Cu, W, Re, Ir, Ni, another suitable conductive material, or multilayers thereof.

The work function metal materials 162N includes a different combination of materials than the work function metal materials 162P, in accordance with some embodiments. The work function metal material 162 may be formed using ALD, PVD, CVD, e-beam evaporation, or another suitable technique. The work function metal materials 162N and 162P may be formed separately for n-channel nanostructure transistors and p-channel nanostructure transistors, which may use different work function materials.

A planarization process such as CMP may be performed on the semiconductor structure 100 to remove the materials of the gate dielectric layer 160 and the work function metal material 162 formed above the upper surface of the first interlayer dielectric layer 140, in accordance with some embodiments.

The interfacial layer 158, the gate dielectric layer 160 and the metal gate electrode layer (including the work function metal materials 162N and 162P) are combined to form a final gate stack 162, in accordance with some embodiments. The final gate stack 164 is wrapped around the nanostructures 108, in accordance with some embodiments. In some embodiments, the final gate stack 164 extends in the Y direction.

The final gate stack 164 wrapped around the nanostructures 108 is combined with the neighboring source/drain features 130N and 130P to form nanostructure transistors. In some embodiments, the nanostructure transistors formed over the lower fin element 103P (in the p-type well) are n-channel nanostructure transistors, and the nanostructure transistors formed over the lower fin element 103N (in the n-type well) are p-channel nanostructure transistors. The final gate stack 164 may engage the channel region so that current can flow between the source/drain features 130 during operation.

Gate isolation structures 166 are formed through the final gate stack 164, the gate spacer layers 120, the fin isolation structures 144 and the first interlayer dielectric layer 140, as shown in FIGS. 3H-2 and 3H-3, in accordance with some embodiments. In some embodiments, the gate isolation structures 166 extend in the X direction. The final gate stack 164 is cut through by the gate isolation structures 166 into several segments which are physically and electrically isolated from each other, in accordance with some embodiments. The gate isolation structures 166 may be also referred to as cut metal gate (CMG) pattern.

The gate isolation structures 166 are made of a dielectric material such as silicon nitride (SiN), silicon oxynitride (SiON), silicon carbon nitride (SiCN), silicon oxycarbonitride (SiOCN), oxygen-doped silicon carbonitride (Si(O)CN), silicon oxide (SiO₂), or a combination thereof. In some embodiments, the gate isolation structures 166 include dielectric material with a dielectric constant value greater than 7.9, such as LaO, AlO, AlON, ZrO, HfO, ZnO, ZrN, ZrAlO, TiO, TaO, YO, TaCN, or a combination thereof.

The formation of the gate isolation structures 166 includes patterning the semiconductor structure 100 to form gate-cut openings using photolithography and etching processes, depositing a dielectric material to overfill the gate-cut openings, in accordance with some embodiments. A planarization process (e.g., CMP, etching back process, or a combination thereof) is then performed on the dielectric material until the first interlayer dielectric layer 140 is exposed, in accordance with some embodiments.

FIGS. 3I-1 to 3I-3 illustrate a semiconductor structure 100 after the formation of an etching stop layer 168, a second interlayer dielectric layer 170, contact plugs 172, an etching stop layer 176, a second interlayer dielectric layer 178, and vias 180 and 182, in accordance with some embodiments.

An etching stop layer 168 and a second interlayer dielectric layer 170 are sequentially formed over the semiconductor structure 100, as shown in FIGS. 3I-1 to 3I-3, in accordance with some embodiments. In some embodiments, the etching stop layer 168 is made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, the second interlayer dielectric layer 170 is made of dielectric material, such as USG, BPSG, FSG, PSG, BSG, and/or another suitable dielectric material. In some embodiments, the etching stop layer 168 and the second interlayer dielectric layer 170 are deposited using CVD (such as HDP-CVD, PECVD, HARP or FCVD), another suitable technique, or a combination thereof.

The contact plugs 172 are formed through the second interlayer dielectric layer 170, the etching stop layer 168, the first interlayer dielectric layer 140 and the contact etching stop layers 136 and 138, in accordance with some embodiments. The contact plugs 172 land on the source/drain features 130N and 130P, in accordance with some embodiments. In some embodiments, the formation of the contact plugs 172 includes patterning the semiconductor structure e 100 to form contact openings using photolithography and etching processes until the source/drain features 130N/130P are exposed.

Silicide layers 174 are formed on the exposed surfaces of the source/drain features 130N and 130P, in accordance with some embodiments. In some embodiments, the silicide layers 174 are made of WSi, NiSi, TiSi and/or CoSi. In some embodiments, the formation of the silicide layers 174 includes depositing a metal material followed by one or more annealing processes. The semiconductive material (e.g., Si) from the source/drain features 130N and 130P reacts with the metal material to form the silicide layers 174, in accordance with some embodiments. Unreacted metal material is then removed, e.g., using wet etching.

Contact liners 175 are formed along the sidewalls of the contact openings using a deposition process followed by an etching back process, in accordance with some embodiments. In some embodiments, the contact liners 166 are made of an insulating material such as a dielectric material (e.g., SiC, LaO, AlO, AlON, ZrO, HfO, SiN, ZnO, ZrN, ZrAlO, TiO, TaO, YO, TaCN, ZrSi, SiOCN, SiOC, SiCN, SiN, HfSi, or SiO); or undoped silicon (Si).

Afterward, one or more conductive materials for the contact plugs 172 are deposited using CVD, PVD, e-beam evaporation, ALD, ECP, ELD, another suitable method, or a combination thereof to overfill the contact openings, in accordance with some embodiments. The one or more conductive materials over the second interlayer dielectric layer 170 are planarized using, for example, CMP.

The contact plugs 172 may have a multilayer structure. For example, a barrier/adhesive layer (not shown) may optionally be deposited along the sidewalls and the bottom surfaces of the contact openings. The barrier/adhesive layer may be made of tantalum (Ta), tantalum nitride (TaN), titanium (Ti), titanium nitride (TiN), cobalt tungsten (CoW), another suitable material, or a combination thereof. A metal bulk layer is then deposited on the barrier/adhesive layer (if formed) to fill the remainder of the contact openings. In some embodiments, the metal bulk layer is made of one or more conductive materials with low resistance and good gap-fill ability, for example, cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof.

An etching stop layer 176 and a third interlayer dielectric layer 178 are sequentially formed over the semiconductor structure 100, as shown in FIGS. 3I-1 to 3I-3, in accordance with some embodiments. In some embodiments, the etching stop layer 176 is made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, the third interlayer dielectric layer 178 is made of dielectric material, such as USG, BPSG, FSG, PSG, BSG, and/or another suitable dielectric material. In some embodiments, the etching stop layer 176 and the third interlayer dielectric layer 178 are deposited using CVD (such as HDP-CVD, PECVD, HARP or FCVD), another suitable technique, or a combination thereof.

Vias 180 are formed through the third interlayer dielectric layer 178 and the etching stop layer 176 and land on the contact plugs 172, and a via 182 is formed through the third interlayer dielectric layer 178, the etching stop layer 176, the second interlayer dielectric layer 170 and the etching stop layer 168 and lands on the gate stack 164, as shown in FIGS. 3I-2 and 3I-3, in accordance with some embodiments. The vias 180, electrically connected to source/drain terminals of the nanostructure transistors through the contact plugs 172, may be also referred to as source/drain vias (VS or VD), in accordance with some embodiments. The via 182, electrically connected to the gate terminals of the nanostructure transistors, may be also referred to as gate via (VG).

In some embodiments, the formation of the vias 180 and 182 includes patterning the semiconductor structure 100 to form via openings using photolithography and etching processes. Afterward, one or more conductive materials are deposited using CVD, PVD, e-beam evaporation, ALD, ECP, ELD, another suitable method, or a combination thereof to overfill the via openings, in accordance with some embodiments. The one or more conductive materials over the upper surface of the third interlayer dielectric layer 178 are planarized using, for example, CMP.

The vias 180 and 182 may have a multilayer structure. For example, a barrier/adhesive layer (not shown) may optionally be deposited along the sidewalls and the bottom surfaces of the via openings. The barrier layer may be made of Ta, TaN, Ti, TiN, CoW, another suitable material, or a combination thereof. A metal bulk layer is then deposited on the barrier/adhesive layer (if formed) to fill the remainder of the via openings. In some embodiments, the metal bulk layer is made of one or more conductive materials, such as Co, Ni, W, Ti, Ta, Cu, Rh, Ir, Pt, Al, Ru, Mo, or a combination thereof.

In some embodiments, the portion of the first interlayer dielectric layer 140 in the STI recess 123 (FIG. 3B-2) has a dimension DI in a range from about 15 nm to about 25 nm. In some embodiments, the first interlayer dielectric layer 140 has a height H1 measured from the bottom 123B of the STI recess 123 (FIG. 3B-2). The height H1 is in a range from about 100 nm to about 120 nm.

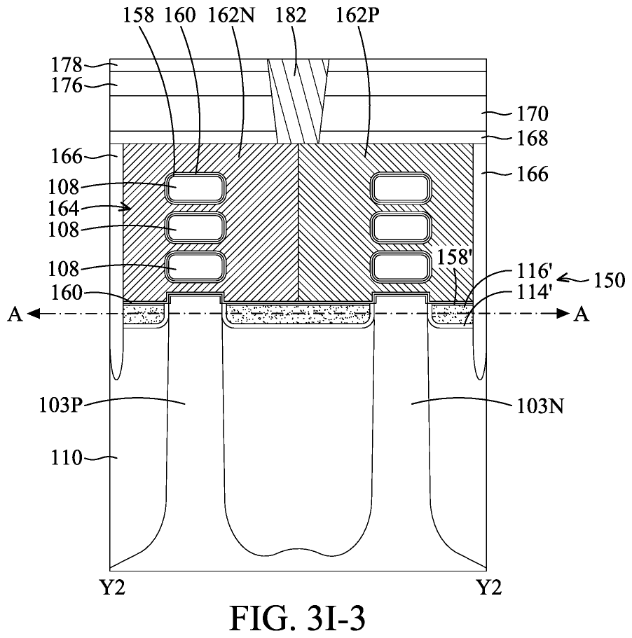

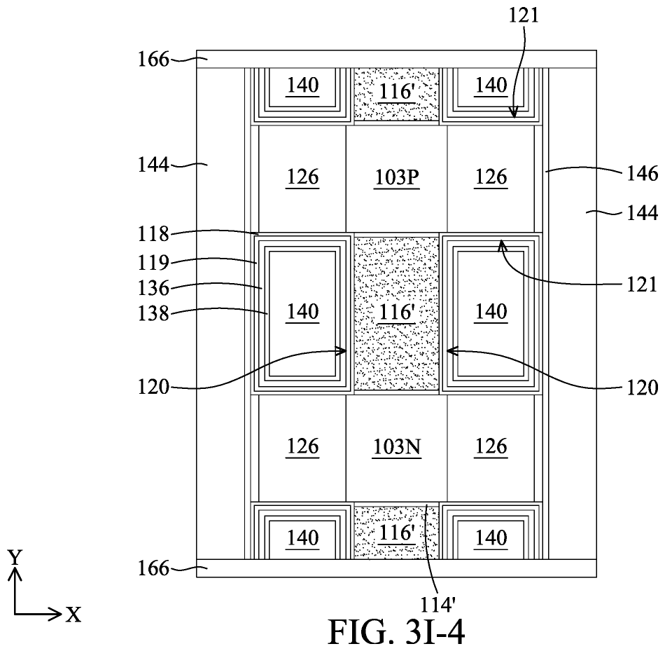

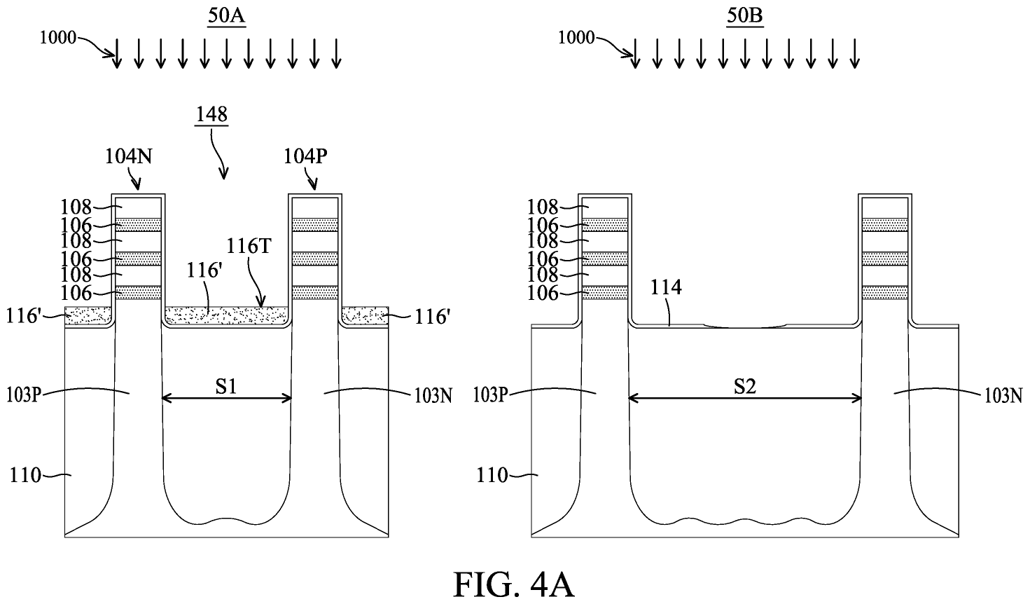

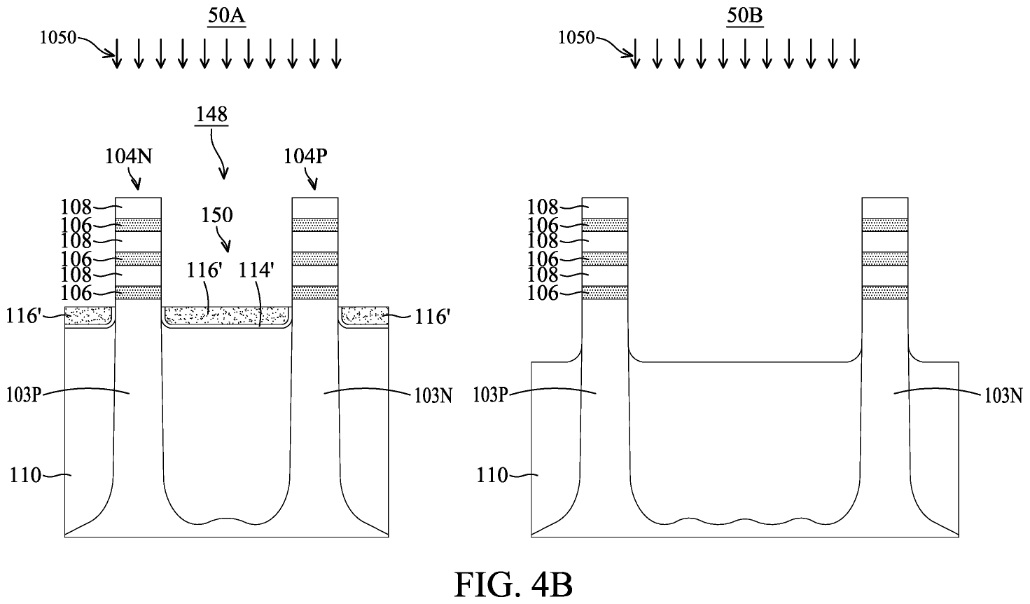

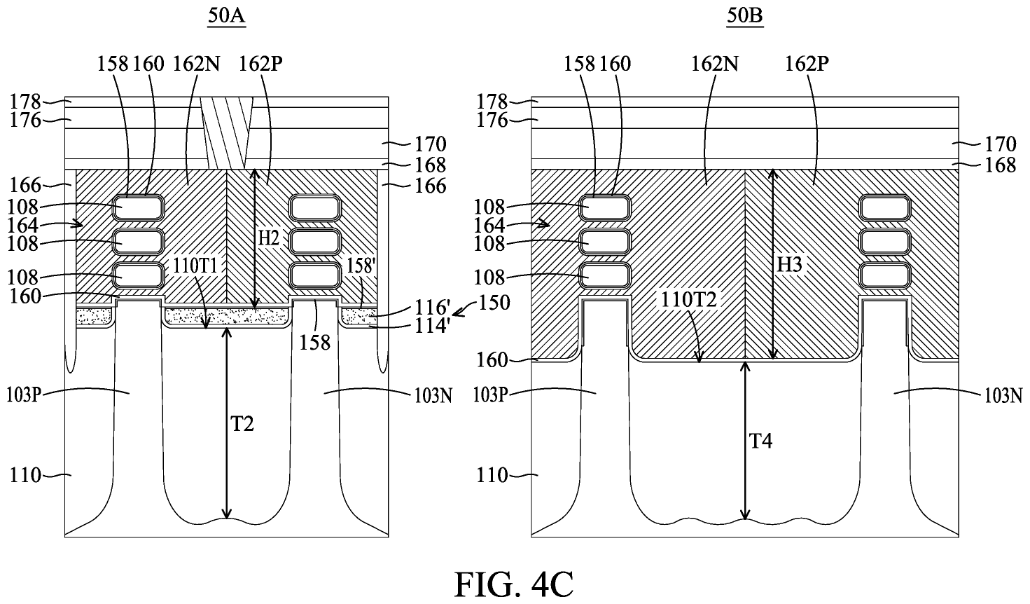

FIG. 3I-4 is a plan view illustrating the semiconductor structure 100 cutting through plan A-A of FIGS. 3I-1 and 3I-3, in accordance with some embodiments. In the X direction, the protection features 150 are defined between the gate spacer layers 120, in accordance with some embodiments. In the X direction, the protection features 150 are defined between the lower fin element 103N and 103P.

In accordance with the embodiments of the present disclosure, the protection features 150 may prevent the loss of the portion of the isolation structure 110 immediately adjacent to the channel regions, which may prevent the enlargement of the final gate stacks 164 toward the isolation structure 110. Therefore, the parasitic capacitance between the gate stack and the source/drain features (i.e., Cgs and Cgd) may be improved, thereby enhancing the performance (e.g., RO (ring Oscillator) performance, AC performance) of the resulting semiconductor device, in accordance with some embodiments.

It should be understood that the semiconductor structure 100 may undergo further CMOS processes to form various features over the semiconductor structure, such as a multilayer interconnect structure (e.g., contact plugs to final gate stack and/or to source/drain features, conductive vias, metal lines, intermetal dielectric layers, passivation layers, etc.).

FIGS. 4A to 4C are cross-sectional views illustrating the formation of a semiconductor structure at various intermediate stages, in accordance with some embodiments of the disclosure. The embodiments of FIGS. 4A to 4C are similar to the embodiments of FIGS. 3A-1 to 3I-3 except that the semiconductor structure 100 includes a pattern-dense region 50A and a patterned-loose region 50B.

FIGS. 4A and 4B illustrate etching processes 1000 and 1050 for forming the gate trenches 148, in accordance with some embodiments of the disclosure.

In some embodiments, the semiconductor structure 100 includes a pattern-dense region 50A in which functional circuits are formed and a patterned-loose region 50B in which dummy circuits are formed. In some embodiments, the pattern density (e.g., active regions 104, dummy gate structures 112, etc.) in the pattern-dense region 50A is higher than the pattern density in the patterned-loose region 50B.

For example, in some embodiments, the spacing S1 between the active regions 104 in the pattern-dense region 50A is less than the spacing S2 between the active regions 104 in the pattern-loose region 50B. In addition, in some embodiments, the spacing (not shown) between the dummy gate structures 112 in the pattern-dense region 50A is less than the spacing (not shown) between the dummy gate structures 112 in the pattern-loose region 50B.

Continuing from FIGS. 3C-1 to 3C-3, a first etching process 1000 is performed to recess the dummy gate electrode layer 116, thereby forming gate trenches 148, as shown in FIG. 4A, in accordance with some embodiments. Due to the etching loading effect, the etching rate in the pattern-loose region 50B is faster than the etching rate in the pattern-loose region 50B, in accordance with some embodiments. The dummy gate electrode layer 116 in the pattern-loose region 50B may be substantially completely removed, in accordance with some embodiments.

In some embodiments, the dummy gate dielectric layer 114 may be opened to expose the isolation structure 110 while the dummy gate electrode layer 116′ in the pattern-dense region 50A remains on the isolation structure 110. As a result, the processing time of the first etching process 1000 may be precisely controlled by end-point mode, for example, detecting the Si/O signal, thereby allowing the remaining dummy gate electrode layer 116′ in the pattern-dense region 50A to have a desirable thickness.

A second etching process 1050 is performed to etch away the dummy gate dielectric layer 114, as shown in FIG. 4B, in accordance with some embodiments. During the second etching process 1050, the isolation structure 110 in the pattern-loose region 50B is recessed while the remaining dummy gate electrode layer 116′ protects the isolation structure 110 in the pattern-dense region 50A from being recessed.

The steps described above in FIGS. 3F-1 to 3I-3 are performed, thereby forming the final gate stacks 164, the gate isolation structures 166, contact plugs 172 and vias 180 and 182, as shown in FIG. 4C, in accordance with some embodiments. In some embodiments, the top surface 110T1 of the isolation structure 110 in the pattern-dense region 50A is higher than the top surface 110T2 of the isolation structure 110 in the pattern-loose region 50B.

In some embodiments, the thickness T2 of the isolation structure 110 directly under the protection features 150 in the pattern-dense region 50A is greater than the thickness T4 of the isolation structure 110 directly under the final gate stack 164 in the pattern-loose region 50B. In some embodiments, the height H2 of the final gate stack 164 in the pattern-dense region 50A is less than the height H3 of the final gate stack 164 in the pattern-loose region 50B.

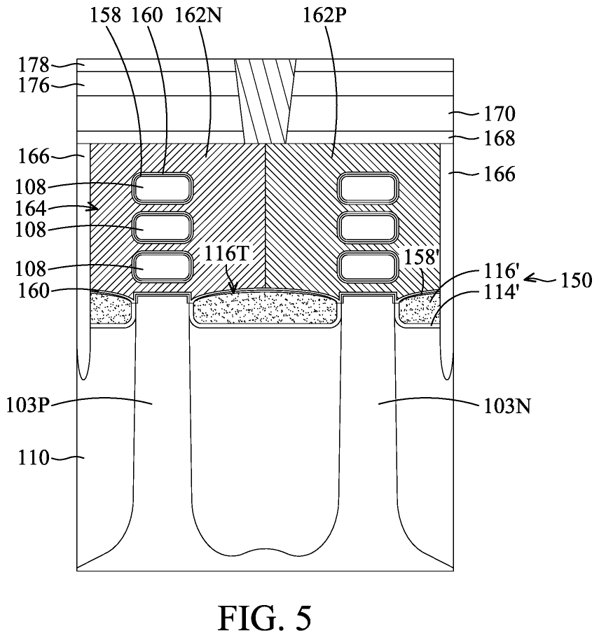

FIG. 5 is a modification of the semiconductor structure of FIG. 3I-3, in accordance with some embodiments of the disclosure. The embodiments of FIG. 5 are similar to the embodiments of FIGS. 3A-1 to 3I-3 except for the profile of the top surface of the remaining dummy gate electrode layer 116′.

In some embodiments, the etching rate of the dummy gate electrode layer 116′ is higher at the edge where it is interfaced with active regions 104 and/or the gate spacer layers 120 than at the center of the dummy gate electrode layer 116′. As a result, in some embodiments, the top surface 116T of the remaining dummy gate electrode layer 116′ is a curve surface, e.g., convex upwards. In some embodiments, the top point of the top surface 116T may be higher than the top surfaces of the lower fin elements 103N and 103P.

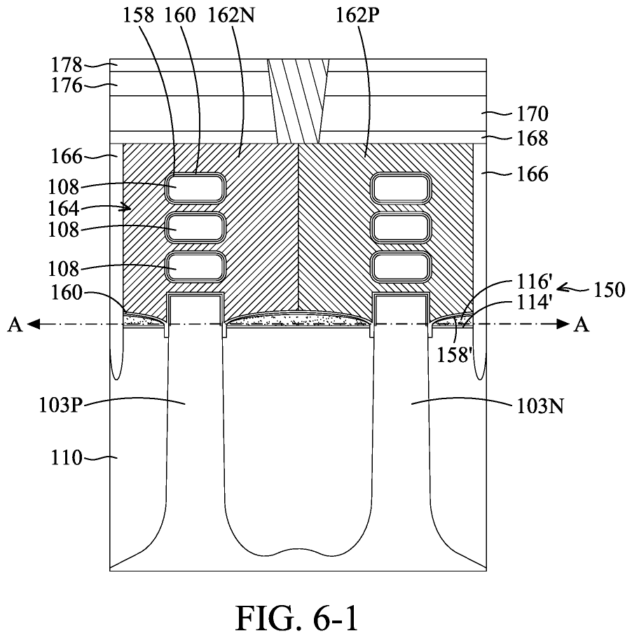

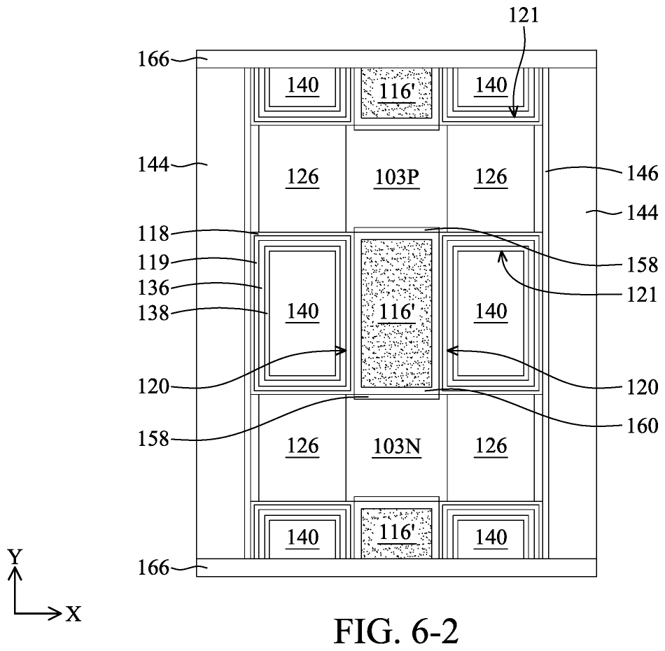

FIG. 6-1 is a modification of the semiconductor structure of FIG. 5, in accordance with some embodiments of the disclosure. FIG. 6-2 is a plan view illustrating the semiconductor structure cutting through plan A-A of FIG. 3I-1, in accordance with some embodiments of the disclosure. The embodiments of FIGS. 6-1 and 6-2 are similar to the embodiments of FIG. 5 except that the isolation structure 110 is partially recessed.

In the etching processes 1000 and 1050, the portion of the dummy gate electrode layer 116 and the dummy gate dielectric layer 114 at the edge where it is interfaced with active regions 104 and the gate spacer layers 120 may be opened to expose the isolation structure 110, in accordance with some embodiments. The isolation structure 110 is further etched to form recesses, and the gate dielectric layer 160 is formed to fill the recesses, in accordance with some embodiments. In some embodiments, the remaining dummy gate electrode layer 116′ is surrounded by the gate dielectric layer 160, as shown in FIG. 6-2.

The protection features 150 may mitigate the loss of the portion of the isolation structure 110 immediately adjacent to the channel regions. Therefore, the parasitic capacitance between the gate stack and the source/drain features may be improved, thereby enhancing the performance of the resulting semiconductor device, in accordance with some embodiments.

As described above, the semiconductor structure 100 includes a protection feature 150 on the isolation structure 110. The protection feature 150 is formed from the remaining dummy gate electrode layer 116′ and the remaining dummy gate electrode layer 114′. The protection features 150 may prevent or mitigate the loss of the isolation structure 110, thereby preventing the enlargement of the final gate stack 164. Therefore, the performance of the resulting semiconductor device may be improved, in accordance with some embodiments.

Embodiments of a semiconductor structure and the method for forming the same may be provided. The method for forming the semiconductor structure includes forming a dummy gate structure across an active region and an isolation structure, partially etching the gate structure to leave the remaining portion on the isolation structure, and forming a gate stack on the remaining portion of the dummy gate. Because the dummy gate structure is not completely removed, and remains to protect the isolation structure. Therefore, the performance of the resulting semiconductor device may be improved, in accordance with some embodiments.

In some embodiments, a method for forming a semiconductor structure is provided. The method includes forming a fin structure in which first semiconductor layers and second semiconductor layers are alternately stacked over a fin element, forming an isolation structure to surround the fin element, forming a dummy gate dielectric layer across the fin structure over the isolation structure, forming a dummy gate electrode layer on the dummy gate dielectric layer, partially etching the dummy gate electrode layer and the dummy gate dielectric layer to form a trench, removing the first semiconductor layers to form gaps, and forming a gate stack on a remaining portion of the dummy gate electrode layer and filling the trench and the gaps.

In some embodiments, a method for forming a semiconductor structure is provided. The method includes forming a plurality of first active regions in a first region of the substrate, forming an isolation structure to surround lower portions of the plurality of first active regions, forming a first dummy gate structure over the plurality of first active regions, and etching the first dummy gate structure. A remaining portion of the first dummy gate structure is provided on the isolation structure. The method includes patterning upper portions of the plurality of first active regions to form a plurality of first nanostructures, and forming a first gate stack to surround the plurality of first nanostructures.

In some embodiments, a semiconductor structure is provided. The semiconductor structure includes a plurality of nanostructures over a fin element, an isolation structure surrounding the fin element, a protection feature over the isolation structure and surrounding the fin element, and a gate stack over the protection feature and wrapping around the plurality of nanostructures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming a fin structure in which first semiconductor layers and second semiconductor layers are alternately stacked over a fin element;
forming an isolation structure to surround the fin element;
forming a dummy gate dielectric layer across the fin structure over the isolation structure;
forming a dummy gate electrode layer on the dummy gate dielectric layer;
partially etching the dummy gate electrode layer and the dummy gate dielectric layer to form a trench;
removing the first semiconductor layers to form gaps; and
forming a gate stack on a remaining portion of the dummy gate electrode layer and filling the trench and the gaps.

2. The method for forming the semiconductor structure as claimed in claim 1, wherein the remaining portion of the dummy gate electrode layer has a top surface that is lower than a top surface of the fin element.

3. The method for forming the semiconductor structure as claimed in claim 1, wherein forming the gate stack on the remaining portion of the dummy gate electrode layer and filling the trench and gaps comprises:
forming interfacial layers on the second semiconductor layers;
forming a gate dielectric layer over the interfacial layers; and
forming a metal gate electrode layer over the gate dielectric layer.

4. The method for forming the semiconductor structure as claimed in claim 3, further comprising:
forming an oxide layer on the remaining portion of the dummy gate electrode layer while forming the interfacial layers.

5. The method for forming the semiconductor structure as claimed in claim 1, wherein the remaining portion of the dummy gate electrode layer protects the isolation structure from being recessed.

6. The method for forming the semiconductor structure as claimed in claim 1, wherein the remaining portion of the dummy gate electrode has a convex top surface.

7. The method for forming the semiconductor structure as claimed in claim 1, further comprising:
recessing the isolation structure to form a recess between the remaining portion of the dummy gate electrode and the fin element, wherein the gate stack further fills the recess.

8. The method for forming the semiconductor structure as claimed in claim 7, wherein the gate stack includes a gate dielectric layer, and in a plan view, the gate dielectric layer surrounds the remaining portion of the dummy gate electrode layer.

9. The method for forming the semiconductor structure as claimed in claim 1, wherein after removing the first semiconductor layers to form gaps, a remaining portion of the dummy gate dielectric layer remains between the remaining portion of the dummy gate electrode layer and the isolation structure.

10. A method for forming a semiconductor structure, comprising:
forming a plurality of first active regions in a first region of the substrate;
forming an isolation structure to surround lower portions of the plurality of first active regions;
forming a first dummy gate structure over the plurality of first active regions;
etching the first dummy gate structure, wherein a remaining portion of the first dummy gate structure is provided on the isolation structure;
patterning upper portions of the plurality of first active regions to form a plurality of first nanostructures; and
forming a first gate stack to surround the plurality of first nanostructures.

11. The method for forming the semiconductor structure as claimed in claim 10, wherein the first gate stack is formed on the remaining portion of the first dummy gate structure.

12. The method for forming the semiconductor structure as claimed in claim 10, further comprising:
forming a plurality of second active regions in a second region of the substrate, wherein a first spacing between adjacent two of the first active regions is less than a second spacing between adjacent two of the second active regions;
forming the isolation structure to surround lower portions of the plurality of second active regions;
forming a second dummy gate structure over the plurality of second active regions;
etching the second dummy gate structure to expose the isolation structure; and
patterning the plurality of second active regions to form a plurality of second nanostructures; and
forming a second gate stack to surround the plurality of second nanostructures.

13. The method for forming the semiconductor structure as claimed in claim 12, wherein after etching the first dummy gate structure and etching the second dummy gate structure, a top surface of a first portion of the isolation structure in the first region is higher than a top surface of a second portion of the isolation structure in the second region.

14. The method for forming the semiconductor structure as claimed in claim 10, wherein the first dummy gate structure includes a dummy gate dielectric layer and a dummy gate electrode layer over the dummy gate dielectric layer, and etching the first dummy gate structure comprises:
etching the dummy gate electrode layer to expose a first portion of the dummy gate dielectric layer while a second portion of the dummy gate dielectric layer remains covered by the dummy gate electrode layer; and
etching the first portion of the dummy gate dielectric layer to expose the plurality of first active regions.

15. A semiconductor structure, comprising:
a plurality of nanostructures over a fin element;
an isolation structure surrounding the fin element;
a protection feature over the isolation structure and surrounding the fin element; and
a gate stack over the protection feature and wrapping around the plurality of nanostructures.

16. The semiconductor structure as claimed in claim 15, wherein the protection feature comprises a semiconductor layer and a dielectric layer between the isolation structure and the semiconductor layer.

17. The semiconductor structure as claimed in claim 16, wherein the semiconductor layer has a curved top surface facing the gate stack.

18. The semiconductor structure as claimed in claim 16, wherein the dielectric layer is interposed between the semiconductor layer and the fin element.

19. The semiconductor structure as claimed in claim 15, further comprising:
gate spacer layers along sidewalls of the gate stack and sidewalls of the protection feature.

20. The semiconductor structure as claimed in claim 15, further comprising:
a source/drain feature on the fin element; and
an interlayer dielectric layer over the source/drain feature, wherein a top surface of a first portion of the isolation structure directly under the interlayer dielectric layer is lower than a top surface of a second portion of the isolation structure directly under the protection feature.
